(19) United States
(12) Patent Application Publication
(10) Pub. No.: US 2021/0327912 A1
(43) Pub. Date: Oct. 21, 2021

(54) DISPLAY PANEL AND METHOD FOR FABRICATING SAME

(71) Applicant: WUHAN CHINA STAR OPTOELECTRONICS SEMICONDUCTOR DISPLAY TECHNOLOGY CO., LTD., Wuhan (CN)

(72) Inventor: Kai Hu, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/623,449

(22) PCT Filed: Sep. 17, 2019
(86) PCT No.: PCT/CN2019/106258

§ 371 Date: Dec. 17, 2019

(30) Foreign Application Priority Data
Aug. 21, 2019 (CN) 201910773342.X

(51) Int. Cl. H01L 27/12

(52) U.S. Cl. CPC H01L 27/1218; H01L 27/3262; H01L 27/1262

(57) ABSTRACT

A display panel and a method for fabricating the same are provided. The display panel includes a substrate including a substrate body and a trench recessed below a surface on a side of the substrate body, and a first thin film transistor disposed in the trench. The method for fabricating the display panel includes a substrate providing step, a substrate etching step, and a thin film transistor fabricating step.

### FIELD OF INVENTION

The present invention relates to a display technology, and more particularly to a display panel and a method for fabricating the same.

### BACKGROUND

When people use mobile phones for work or watching videos, they will always find problems, such as eyestrain caused by screens that are too small. Flexible, foldable screens can some solve these problems to some extent. Flexible, foldable active-matrix organic light-emitting diode (AMOLED) screens are favored by many manufacturers due to their large color gamut, strong contrast, wide viewing angles, high resolution, light weight, and flexibility.

The flexible AMOLED panel mainly comprises the following parts: a flexible substrate, a thin film transistor (TFT), an OLED, and an encapsulation layer. Due to brittleness of the inorganic layer, the TFT device of the AMOLED panel is prone to TFT failure during folding, thereby causing malfunction of the screen or failure to illuminate.

Conventional AMOLED panels are densely arranged in a plane in a sub-pixel of the active area. An advantage of this arrangement is that subpixels can be closely arranged to achieve higher pixel density (i.e., pixels per inch, PPI) and full high definition (FHD). However, when such a planar tightness is arranged in a curved state, a thin film transistor (TFT) device is susceptible to a large tensile or compressive stress, resulting in failure of a thin film transistor (TFT), which causes a problem that the screen cannot be normally turned on.

### Technical Problem

An object of the present invention is to solve the technical problem that the thin film transistor is easily damaged during folding of the display panel.

### Technical Solution

In order to achieve the above object, the present invention provides a display panel comprising: a substrate comprising a substrate body and a trench recessed below a surface on a side of the substrate body; and a first thin film transistor disposed in the trench.

Furthermore, a second thin film transistor is disposed over the surface of the side of the substrate body.

Furthermore, the first thin film transistor and the thin film transistor are disposed on the same side of the substrate body.

Furthermore, the first thin film transistor or the second thin film transistor comprises: a spacer layer attached to a bottom and an inner sidewall of the trench, or attached to the surface of the substrate body; a buffer layer disposed over a surface of the spacer layer on a side away from the substrate; an active layer disposed over a surface of the buffer layer on a side away from the barrier layer; a first gate insulating layer disposed over a surface of the active layer and the buffer layer on a side away from the barrier layer; a first gate layer disposed over a surface of the first gate insulating layer on a side away from the buffer layer and disposed opposite to the active layer; a second gate insulating layer disposed over a surface of the first gate layer and the first gate insulating layer on a side away from the buffer layer; a second gate layer disposed over a surface of the second gate insulating layer away from the first gate insulating layer and disposed opposite to the first gate layer; a first dielectric layer disposed over a surface of the second gate layer and the second gate insulating layer on a side away from the first gate insulating layer; and a second dielectric layer disposed over a surface of the first dielectric layer on a side away from the second gate insulating layer.

Furthermore, the first thin film transistor or the second thin film transistor further comprises a source drain layer disposed over a surface of the second dielectric layer on a side away from the first dielectric layer, passing through the second dielectric layer, the first dielectric layer, the second gate insulating layer, and the first gate insulating layer to connect the active layer.

Furthermore, the display panel further comprises a planarization layer disposed over a surface of the first thin film transistor or the second thin film transistor away from the substrate; an anode layer disposed over a surface of the planarization layer away from the thin film transistor or the thin film transistor, and is connected to the source and drain layer through the planarization layer; a pixel defining layer disposed over a surface of the anode layer and the planarization layer away from the first thin film transistor or the second thin film transistor; a through hole penetrating the pixel defining layer and disposed opposite to the anode layer; and a spacer disposed over a surface of the pixel defining layer on a side away from the planarization layer.

Furthermore, the through hole comprises: a first through hole disposed opposite to the first thin film transistor; a second through hole disposed opposite to the second thin film transistor; and the first through hole is spaced from the second through hole.

In order to achieve the above object, the present invention also provides a method for fabricating a display panel, comprising the steps of: a substrate providing step of providing a substrate comprising a substrate body; a substrate etching step of etching the substrate body to form a trench, the trench being recessed below a surface of a side of the substrate body; and a thin film transistor fabricating step of fabricating a thin film transistor at the trench, a portion of which is disposed inside the trench.

Furthermore, the substrate etching step comprises: a photoresist coating step of coating a layer of photoresist over an upper surface of the substrate body; an exposure step of performing an exposure process over the upper surface of the photoresist to form a trench; and a photoresist removal step to remove the photoresist.

Furthermore, the thin film transistor fabricating step comprises: a barrier layer fabricating step of fabricating a barrier layer on the bottom and inner sidewalls of the trench and an upper surface of the substrate body; a buffer layer fabricating step of fabricating a buffer layer over an upper surface of the barrier layer; and an active layer fabricating step of fabricating an active layer over the buffer layer in the trench and an upper surface of the buffer layer over the substrate body.

### Advantageous Effects

The technical performances of the present invention is that a s trench etched on the upper surface of the flexible substrate, and the flexible substrate has a less thickness at the trench, so that stress generated by the substrate at the trench is smaller while the flexible substrate is folded. A thin film transistor (TFT) of a pixel driving circuit is placed in the trench, and the TFT is subjected to smaller stress as well. Therefore, during the folding process of the flexible display panel, the pixel driving circuit will not be easily damaged by the stress, and the service time of the display panel can be effectively extended.

### BRIEF DESCRIPTION OF DRAWINGS

To detailly explain the technical schemes of the embodiments or existing techniques, drawings that are used to illustrate the embodiments or existing techniques are provided. Apparently, the illustrated embodiments are just a part of those of the present disclosure. It is easy for any person having ordinary skill in the art to obtain other drawings without labor for inventiveness.

FIG. 1 is a schematic structural diagram of a display panel according to an embodiment of the present invention.

FIG. 2 is a schematic structural view of a substrate according to an embodiment of the present invention.

FIG. 3 is a flowchart of a method for fabricating a display panel according to an embodiment of the present invention.

FIG. 4 is a flowchart of an etching step of a substrate according to an embodiment of the present invention.

FIG. 5 is a flowchart of fabricating steps of a thin film transistor according to an embodiment of the present invention.

Some components are identified as follows:

1, substrate; 2, pixel drive circuit; 3, planarization layer; 4, anode layer; 5, pixel defining layer; 6, spacer; 11, substrate body; 12, trench;

21, barrier layer; 22, buffer layer; 23, active layer; 24, first gate insulating layer; 25, first gate layer; 26, second gate insulating layer; 27, second gate layer; 28, first dielectric layer; 29, second dielectric layer; 20, source drain layer;

210, first thin film transistor; 220, second thin film transistor;

51, through hole; 511, first through hole; 512, second through hole.

### DETAILED DESCRIPTION

Please refer to the drawings in the drawings, in which the same reference numerals represent the same components. The following description is based on the specific embodiments of the present invention as illustrated and should not be construed as limiting the specific embodiments that are not described herein.

The directional terms mentioned in the present invention, such as “upper”, “lower”, “before”, “after”, “left”, “right”, “inside”, “outside”, “side”, etc., are only used to show direction in the figures. The directional terms used in the drawings are used to explain and explain the invention and are not intended to limit the scope of the invention.

In the drawings, structurally identical components are denoted by the same reference numerals, and structural or functionally similar components are denoted by like reference numerals. Moreover, the size and thickness of each component shown in the drawings are arbitrarily shown for ease of understanding and description, and the invention does not limit the size and thickness of each component.

When a component is described as “on” another component, the component can be placed directly on the other component; there can also be an intermediate component that is placed on the intermediate component, and the intermediate component is placed on another component. When a component is described as “installed to” or “connected to” another component, it can be understood as “directly” or “connected” or a component is “mounted to” or “connected” through an intermediate component to another component.

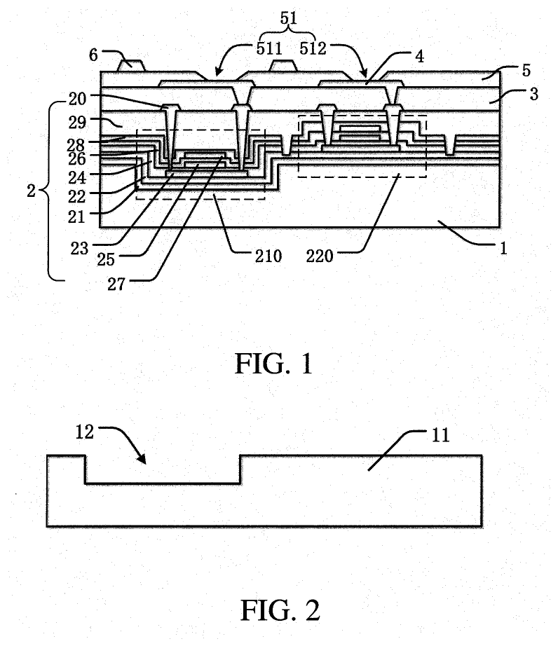

As shown in FIG. 1 to FIG. 2, the present embodiment provides a display panel comprising a substrate 1, a thin film transistor 2, a planarization layer 3, an anode layer 4, a pixel defining layer 5, and a spacer 6.

The substrate 1 is a flexible substrate made of materials such as polyimide (PI). The substrate 1 is a yellow transparent film with a relative density of 1.39 to 1.45. The polyimide film has excellent properties such as high and low temperature resistances, electrical insulation, adhesion, radiation resistances, and medium resistances. It can be used for a long time in the temperature range of −269° C. to 280° C. and can reach a high temperature of 400° C. in a short period of time. The substrate 1 comprises a substrate body 11 having a trench 12 formed downward on an upper surface of the substrate body 11.

The trench 12 is added to the existing flexible substrate, and the flexible substrate at the trench 12 has a less thickness, so that stress generated by the substrate at the trench 12 is small when the substrate 1 is folded.

The trench 12 is disposed in a display area of the display panel, and the plurality of trenches 12 can be disposed. The thin film transistor 2 can be divided into a first thin film transistor 210 and a second thin film transistor 220. The first thin film transistor 210 is disposed in the trench 12, and the second thin film transistor 220 is disposed outside the trench 12, that is, on the upper surface of the substrate 1. The first thin film transistor 210 is spaced apart from the second first thin film transistor 220. The first thin film transistor 2 can be a single first thin film transistor or a plurality of first thin film transistor s alternately disposed inside and outside the trench 12.

The plurality of trenches 12 can be sequentially arranged in the horizontal direction and can also be sequentially arranged in the vertical direction, so that the display panel can be sequentially folded horizontally or vertically while folding thereof.

The first thin film transistor 2 comprises a barrier layer 21, a buffer layer 22, an active layer 23, a first gate insulating layer 24, a first gate layer 25, a second gate insulating layer 26, a second gate layer 27, a first dielectric layer 28, a second dielectric layer 29, and a source drain layer 20.

The barrier layer 21 is attached to the bottom and inner sidewalls of the trench 12 and the upper surface of the substrate body 11. The barrier layer 21 functions to block external moisture and oxygen.

The buffer layer 22 is attached to the upper surface of the barrier layer 21 to serve as a buffer for protecting the first thin film transistor 2.

The active layer 23 is attached to the upper surface of the buffer layer 22, and the material of the active layer 23 is silicon, which has semiconductor properties. The active layer 23 comprises a first active layer and a second active layer. The first active layer is attached to the upper surface of the buffer layer in the trench 12, and the second active layer is attached to the upper surface of the buffer layer over the substrate body 11.

The first gate insulating layer (GI) 24 is attached to the upper surface of the buffer layer 22 and the active layer 23. The material of the first gate insulating layer 24 is usually silicon nitride (SiNx) or silicon oxide. The material of the first gate insulating layer 24 acts as an insulating layer to prevent a short circuit phenomenon in the first thin film transistor 2.

The first gate layer 25 is attached to the upper surface of the first gate insulating layer 24, and is disposed above the active layer 23, opposite to the active layer 23. The first gate layer 25 is made of metal.

The second gate insulating layer (GI) 26 is attached to the upper surface of the first gate insulating layer 24 and the first gate layer 25. The material of the second gate insulating layer 26 is usually silicon nitride (SiNx) or silicon oxide (SiOx), and the second gate insulating layer 26 acts as an insulator to prevent a short circuit in the first thin film transistor 2.

The second gate layer 27 is attached to the upper surface of the second gate insulating layer 26, and is disposed above the first gate layer 25, opposite to the first gate layer 25. The second gate layer 27 is made of a metal.

The first dielectric layer (ILD) 28 is disposed over the upper surfaces of the second gate layer 27 and the second gate insulating layer 26. The first dielectric layer 28 is made of an inorganic material, which generally is silicon oxynitride (SiON), boron and phosphorus doped silicon glass (BPSG), plasma enhanced tetraethyl orthosilicate (PETEOS), and the like.

The second dielectric layer 29 is disposed over the upper surface of the first dielectric layer 28. The second dielectric layer 29 is made of an inorganic material, which generally is silicon oxynitride (SiON), boron and phosphorus doped silicon glass (BPSG), plasma enhanced tetraethyl orthosilicate (PETEOS), and the like. The second dielectric layer 29 is a planarized dielectric layer to facilitate subsequent adhesion of the film layer. The second dielectric layer 29 is used to isolate the second gate layer 27 from the subsequent film layer to prevent a short circuit in the thin film transistor 2 for protecting the circuit structure.

The source drain layers 20 are disposed over the upper surface of the second dielectric layer 29 and are opposite to the active layer 23. The source and drain layers 20 sequentially pass through the second dielectric layer 29 and the first dielectric layer 28 from top to bottom. The second gate insulating layer 26 and the first gate insulating layer 24 are connected to the upper surface of the active layer 23 to form electrical connection between the source drain layers 20 and the active layer 23.

The planarization layer (PLN) 3 is disposed over the upper surfaces of the second dielectric layer 29 and the source and drain layers 20, and the planarization layer 3 is used to planarize the in-plane difference caused by various layer patterns over the substrate 1. The planarization layer 3 can reduce an area of a black matrix, increase an aperture ratio of the display panel, increase transmittance of light, and reduce the power consumption of a product.

The anode layer 4 is disposed over the upper surface of the planarization layer 3 and is connected to the source drain layers 20 through the planarization layer 3, thereby forming electrical connections between the anode layer 4 and the thin film transistor 2.

The pixel defining layer (PDL) 5 is disposed over the upper surfaces of the anode layer 4 and the planarization layer 3 to serve as an insulating layer for defining a size of the light-emitting layer.

The pixel defining layer 5 is provided with a through hole 51. The through hole 51 is disposed opposite to the anode layer 4. A light emitting layer (not shown) can be disposed in the through hole 51. The light emitting layer can be connected to the anode layer 4 to obtain an electrical signal to be a light emitting pixel. The place where the pixel defining layer 5 is covered does not emit light.

The through hole 51 comprises a first through hole 511 and a second through hole 512. The first through hole 511 is opposite to the first thin film transistor 210, and the second through hole 512 is opposite to the second thin film transistor 220. The first through hole 511 is spaced apart from the second through hole 512 such that the light emitting layer in the first through hole 511 can be spaced apart from the light emitting layer in the second through hole 512. The concave and convex directions between adjacent sub-pixels are opposite, that is, the red light emitting layer (R), the green light-emitting layer (G), and the blue light-emitting layer (B) may have a configuration arranged as “concave-convex-concave” or “convex-concave-convex”.

The spacer (SP) 6 is disposed over the upper surface of the pixel defining layer 5 to prevent defects such scratches happened to the pixel defining layer 5 caused by direct contact between a fine metal mask (FMM) and the pixel defining layer 5 when an OLED material is formed by vapor evaporation.

The technical performances of the display panel provided by the present embodiment is that a s trench etched on the upper surface of the flexible substrate, and the flexible substrate has a less thickness at the trench, so that stress generated by the substrate at the trench is smaller while the flexible substrate is folded. A thin film transistor (TFT) of a pixel driving circuit is placed in the trench, and the TFT is subjected to smaller stress as well. Therefore, during the folding process of the flexible display panel, the pixel driving circuit will not be easily damaged by the stress, and the service time of the display panel can be effectively extended.

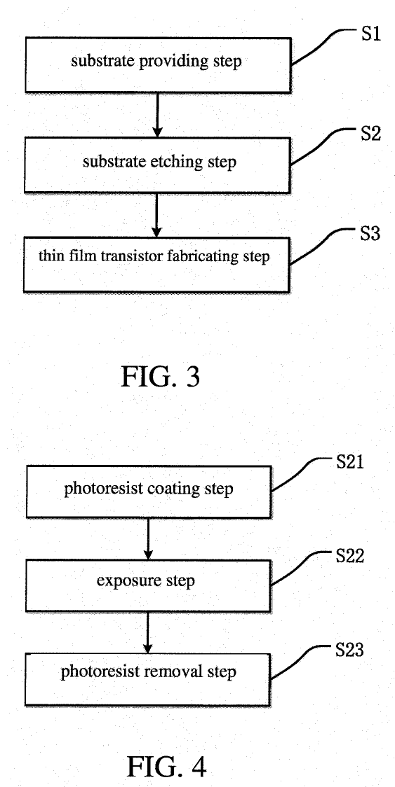

As shown in FIG. 3, the present embodiment further provides a method for fabricating the above display panel, which comprises the following steps S1 to S3.

S1—substrate providing step: a substrate is provided, the substrate comprises a substrate body, and the substrate is a flexible substrate.

S2—substrate etching step: the substrate body is etched, and a trench is formed over the upper surface of the substrate body. As shown in FIG. 4, the substrate etching step specifically comprises steps S21 to S23. S21—photoresist coating step: a photoresist (PR) is coated over the upper surface of the substrate body. S22—exposure step: a mask is provided above the photoresist, and the mask is irradiated with ultraviolet light (UV) to form a trench. S23—photoresist removing step: the mask is removed, and the photoresist is dissolved in a developing solution to removes the photoresist. The trench is formed over the upper surface of the flexible substrate, and the flexible substrate has a less thickness at the trench, and the stress generated over the substrate at the trench is small when the flexible substrate is folded.

S3—thin film transistor fabricating step: thin film transistors are fabricated at the trench and the upper surface of the substrate body, and a part of the thin film transistor is disposed inside the groove. The thin film transistor is disposed in the trench, so that the thin film transistor is less stressed and is not easily damaged, thereby prolonging the service life of the display panel.

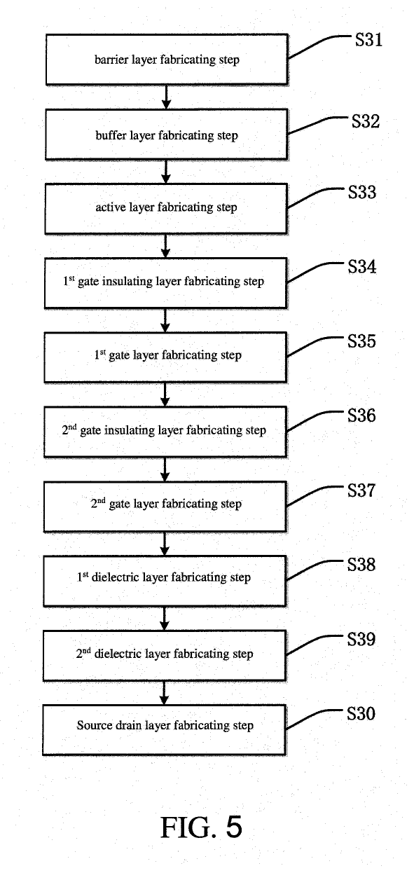

As shown in FIG. 5, the thin film transistor fabricating step comprises steps S31 to S39 and S30.

S31—barrier layer fabricating step: a barrier layer is fabricated over the bottom and inner sidewalls of the trench and the upper surface of the substrate body.

S32—buffer layer fabricating step: a buffer layer is fabricated over the upper surface of the barrier layer, which can be fabricated by deposition or inkjet printing.

S33: active layer fabricating step: a semiconductor material is deposited over an upper surface of the buffer layer, and after patterning, forming a first active layer over an upper surface of the buffer layer in the trench, on the substrate body The upper surface of the buffer layer forms a second active layer. The semiconductor material may be silicon.

S34: first gate insulating layer fabricating step: depositing an inorganic material over the active layer and an upper surface of the buffer layer, and the inorganic material comprises silicon nitride (SiNx) or silicon oxide (SiOx). After the patterning process, a first gate insulating layer is formed.

S35—first gate layer fabricating step: a metal material is deposited over the upper surface of the first gate insulating layer, and a first gate layer is formed after the patterning process. The first gate layer is disposed over the above the active layer, opposite the active layer.

S36—second gate insulating layer fabricating step: an inorganic material is deposited over the upper surface of the first gate insulating layer and the first gate layer, and the inorganic material comprises silicon nitride (SiNx) or silicon oxidation The material is patterned to form a second gate insulating layer.

S37—second gate layer fabricating step: a metal material is deposited over the upper surface of the second gate insulating layer, and a second gate layer is formed after the patterning process. The second gate layer is disposed over the first gate layer and disposed opposite to the first gate layer.

S38—first dielectric layer fabricating step: an inorganic material is deposited over the upper surfaces of the second gate insulating layer and the second gate layer, and the inorganic material comprises silicon oxynitride (SiON), boron and phosphorus doped silicon glass (BPSG), plasma enhanced tetraethyl orthosilicate (PETEOS), etc. The inorganic material is patterned to form the first dielectric layer.

S39—second dielectric layer fabricating step: an inorganic material is deposited over the upper surface of the first dielectric layer, and the inorganic material comprises silicon oxynitride (SiON), boron and phosphorus doped silicon glass (BPSG), plasma enhanced tetraethyl orthosilicate (PETEOS) or the like. A second dielectric layer is formed after planarization.

S30—source drain layer fabricating step: a source drain layer is fabricated over an upper surface of the second dielectric layer, wherein the source and drain layer sequentially pass through the second dielectric layer and the first dielectric layer, the second gate insulating layer, and the first gate insulating layer to connect the active layer.

The technical performances of the method for fabricating a display panel according to the embodiment of the present invention is that a trench is etched over the substrate by using a photoresist, and the flexible substrate has a less thickness at the trench. The substrate at the trench generates less stress when the flexible substrate is folded, and a thin film transistor is fabricated in the trench and the upper surface of the substrate body, and the TFT is also subjected to relatively small stress. Therefore, the thin film transistor is not easily damaged by the stress during the folding process of the flexible display panel, and the service life of the display panel can be effectively extended.

While the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

What is claimed is:

1. A display panel, comprising:
a substrate, comprising:
a substrate body; and
a trench recessed below a surface on a side of the substrate body; and
a first thin film transistor disposed in the trench.

2. The display panel of claim 1, further comprising a second thin film transistor disposed over the surface on the side of the substrate body.

3. The display panel of claim 2, wherein the first thin film transistor and the thin film transistor are disposed on a same side of the substrate body.

4. The display panel of claim 2, wherein the first thin film transistor or the second thin film transistor comprises:
a spacer layer attached to a bottom and an inner sidewall of the trench, or attached to the surface of the substrate body;
a buffer layer disposed over a surface of the spacer layer on a side away from the substrate;
an active layer disposed over a surface of the buffer layer on a side away from the barrier layer;
a first gate insulating layer disposed over a surface of the active layer and the buffer layer on a side away from the barrier layer;
a first gate layer disposed over a surface of the first gate insulating layer on a side away from the buffer layer and disposed opposite to the active layer;
a second gate insulating layer disposed over a surface of the first gate layer and the first gate insulating layer on a side away from the buffer layer;
a second gate layer disposed over a surface of the second gate insulating layer away from the first gate insulating layer and disposed opposite to the first gate layer;
a first dielectric layer disposed over a surface of the second gate layer and the second gate insulating layer on a side away from the first gate insulating layer; and
a second dielectric layer disposed over a surface of the first dielectric layer on a side away from the second gate insulating layer.

5. The display panel of claim 4, wherein the first thin film transistor or the second thin film transistor further comprises:
a source drain layer disposed over a surface of the second dielectric layer on a side away from the first dielectric layer, passing through the second dielectric layer, the first dielectric layer, the second gate insulating layer, and the first gate insulating layer to connect the active layer.

6. The display panel of claim 5, further comprising:
a planarization layer disposed over a surface of the first thin film transistor or the second thin film transistor away from the substrate;
an anode layer disposed over a surface of the planarization layer away from the thin film transistor or the thin film transistor, and is connected to the source and drain layer through the planarization layer;
a pixel defining layer disposed over a surface of the anode layer and the planarization layer away from the first thin film transistor or the second thin film transistor;
a through hole penetrating the pixel defining layer and disposed opposite to the anode layer; and
a spacer disposed over a surface of the pixel defining layer on a side away from the planarization layer.

7. The display panel of claim 6, wherein the through hole comprises:
a first through hole disposed opposite to the first thin film transistor;
a second through hole disposed opposite to the second thin film transistor; and
the first through hole is spaced from the second through hole.

8. A method for fabricating a display panel, comprising the steps of:
a substrate providing step of providing a substrate comprising a substrate body;
a substrate etching step of etching the substrate body to form a trench, the trench being recessed below a surface of a side of the substrate body; and
a thin film transistor fabricating step of fabricating a thin film transistor at the trench, a portion of which is disposed inside the trench.

9. The method of fabricating a display panel of claim 8, wherein the substrate etching step comprises:
a photoresist coating step of coating a layer of photoresist over an upper surface of the substrate body;
an exposure step of performing an exposure process over the upper surface of the photoresist to form a trench; and
a photoresist removal step to remove the photoresist.

10. The method of fabricating a display panel of claim 8, wherein the thin film transistor fabricating step comprises:
a barrier layer fabricating step of fabricating a barrier layer on the bottom and inner sidewalls of the trench and an upper surface of the substrate body;
a buffer layer fabricating step of fabricating a buffer layer over an upper surface of the barrier layer; and
an active layer fabricating step of fabricating an active layer over the buffer layer in the trench and an upper surface of the buffer layer over the substrate body.
